(19) United States
(12) Patent Application Publication
(10) Pub. No.: US 2004/0245635 A1
(43) Pub. Date: Dec. 9, 2004

(54) Methods for forming contacts in semiconductor devices having local silicide regions and semiconductor devices formed thereby

(76) Inventors: Jong-myeong Lee, Gyeonggi-do (KR); Gil-heyun Choi, Gyeonggi-do (KR); Sang-woo Lee, Gyeonggi-do (KR); Hee-sook Park, Seoul (KR); Kyung-in Choi, Seoul (KR); Jung-hun Seo, Gyeonggi-do (KR)

Correspondence Address: MYERS BIGEL SIBLEY & SAJOVEC, PO BOX 37428, RALEIGH, NC, 27627, US

(21) Appl. No.: 10/858,794

(22) Filed: Jun. 2, 2004

(30) Foreign Application Priority Data
Jun. 5, 2003 (KR) 2003-36438

(51) Int. Cl. H01L 23/48; H01L 21/4763

(52) U.S. Cl. 257/751; 438/627; 257/774; 438/629

(57) ABSTRACT

Semiconductor devices and methods of forming a contact in semiconductor devices are provided. A semiconductor substrate is provided with a cell array region and a peripheral circuit region. A polysilicon layer is formed on the semiconductor substrate in the peripheral circuit region. A metal layer is formed on the polysilicon layer. A metal pattern is formed by removing a portion of the metal layer. The metal pattern is annealed to form a local silicide region in the polysilicon layer. A capacitor is formed on the semiconductor substrate in the cell array region after the local silicide region is formed in the polysilicon layer.

### RELATED APPLICATION

This application claims the benefit of priority from Korean Patent Application No. 10-2003-0036438, filed Jun. 5, 2003, the disclosure of which is hereby incorporated herein by reference in its entirety as if set forth fully herein.

### FIELD OF THE INVENTION

The present invention relates to semiconductor devices and, more specifically, to semiconductor resistor devices and methods for forming contacts therein.

### BACKGROUND OF THE INVENTION

The density of devices in integrated circuits (ICs) has continued to increase due, in part, to the continued decrease in device dimensions. As device dimensions are reduced, their contacts can become smaller with higher resistances. Higher resistance of the contacts may adversely affect the performance of the devices. Consequently, reducing contact resistance may allow increased device integration density. One method for reducing the contact resistance of devices in an IC is disclosed in U.S. Pat. No. 6,255,209.

Semiconductor memory devices can include a cell array region that includes one or more unit memory cells, and a peripheral region that includes components for controlling operation for the unit memory cells (e.g., input/output operations to/from the unit memory cells) and which can be adjacent to and around the cell array region. The components in the cell array region and the peripheral circuit region can include transistors or other active devices and resistors or other passive devices. Accordingly, many different processes may be needed to form the various components in the cell array region and the peripheral circuit region. Some components, such as transistors, may be simultaneously formed in the cell array region when the same or other components, such as resistors, are formed in the peripheral circuit region.

Some semiconductor memory devices, such as DRAMs, include capacitors in the cell array region. The capacitors may have a Semiconductor Insulator Semiconductor (SIS) structure, a Metal Insulator Semiconductor (MIS) structure, and/or a Metal Insulator Metal (MIM) structure. In a SIS structured capacitor, the bottom and top electrodes can be formed from polysilicon. In a MIS structured capacitor, the bottom and top electrodes can be formed from metals and polysilicon, respectively. In a MIM structured capacitor, the bottom and top electrodes can be formed from metals. A capacitor can also be formed from metals such as Titanium-nitride which may provide improved capacitance relative to polysilicon.

Some components in a semiconductor memory device can be degraded if they are subjected to high temperatures, such as, for example, about 600° C. or higher. For example, when a capacitor, such as a MIM capacitor, is exposed to high temperature, minute cracks can be caused in the dielectric layer due to differences between the coefficients of thermal expansion of the various layers in the capacitor (e.g., between the bottom electrode, the dielectric layer, and the upper electrode) during the heating and/or cooling of the capacitor. Cracks in the dielectric layer may cause increased leakage current and/or degrade other characteristics of the capacitor. High temperatures can also cause a transformation of the surface morphology of a metal electrode in a capacitor and result in separation and/or weakening of the bond between the metal electrodes and the dielectric layer.

Accordingly, subjecting capacitors and/or other components to high temperatures after they are formed can degrade their characteristics. For example, some MIM capacitor structures should not be exposed to temperatures greater than 500° C.

### SUMMARY OF THE INVENTION

Some embodiments of the present invention provide a method of forming a semiconductor device. A semiconductor substrate is provided with a cell array region and a peripheral circuit region. A polysilicon layer is formed on the semiconductor substrate in the peripheral circuit region. A metal layer is formed on the polysilicon layer. A metal pattern is formed by removing a portion of the metal layer. The metal pattern is annealed to form a local silicide region in the polysilicon layer. A capacitor is formed on the semiconductor substrate in the cell array region after the local silicide region is formed in the polysilicon layer.

Accordingly, the capacitor is formed after the metal pattern is annealed to provide the local silicide region in the polysilicon layer, which may thereby avoid degradation of the capacitor dielectric that may otherwise occur if the capacitor were subjected to the temperatures used to anneal the metal pattern.

In some further embodiments of the present invention, a first insulating layer is formed on the semiconductor substrate in the cell array region and in peripheral circuit region. The polysilicon layer is formed on the first insulating layer opposite to the semiconductor substrate. The capacitor is formed on the first insulating layer in the cell array region after forming the local silicide region in the polysilicon layer. A second insulation layer is formed on the first insulation layer, the polysilicon layer, and the capacitor. A contact hole is formed through the second insulation layer to expose at least a portion of the local silicide region. A plug is formed in the contact hole. A metal interconnection that is electrically connected to the plug is formed on the second insulation layer. The local silicide region in the polysilicon layer may be wider than the contact hole in the second insulation layer that exposes a portion of the local silicide region.

In yet some further embodiments of the present invention, a resistor layer is formed in the contact hole on the second insulating layer and on the local silicide region. A diffusion barrier layer is formed in the contact hole on the resistor layer opposite the second insulating layer. The plug is formed on the diffusion barrier layer.

Some other embodiments of the present invention provide a semiconductor device. The semiconductor device includes a semiconductor substrate with a cell array region and a peripheral circuit region. A polysilicon layer is on the semiconductor substrate in the peripheral circuit region. A local silicide region is in the polysilicon layer, and includes silicon (Si) and Titanium (Ti), Tantalum (Ta), Nickel (Ni), Cobalt (Co), and/or Tungsten (W). A capacitor is on the semiconductor substrate in the cell array region. An insulation layer is on the polysilicon layer and the capacitor. A contact hole extends through the insulation layer and exposes a portion of the local silicide region. The local silicide region is wider than the contact hole. A plug is in the contact hole. A metal interconnection is on the insulation layer and electrically connected to the plug.

### BRIEF DESCRIPTION OF THE DRAWINGS

FIGS. 1 to 8 are cross-sectional views that illustrate fabrication of a contact in a semiconductor resistor device according to some embodiments of the present invention.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout. It will be understood that when elements are referred to as being “on” or “connected to” one another, they may be “directly on” or “directly connected to” each other or one or more intervening elements may be present. In contrast, when an element is referred to as being “directly on” or “directly connected” to another element, there are no intervening elements present. In the drawings, the thickness of the layers and regions are exaggerated for clarity. As used herein the term “and/or” includes any and all combinations of one or more of the associated listed items.

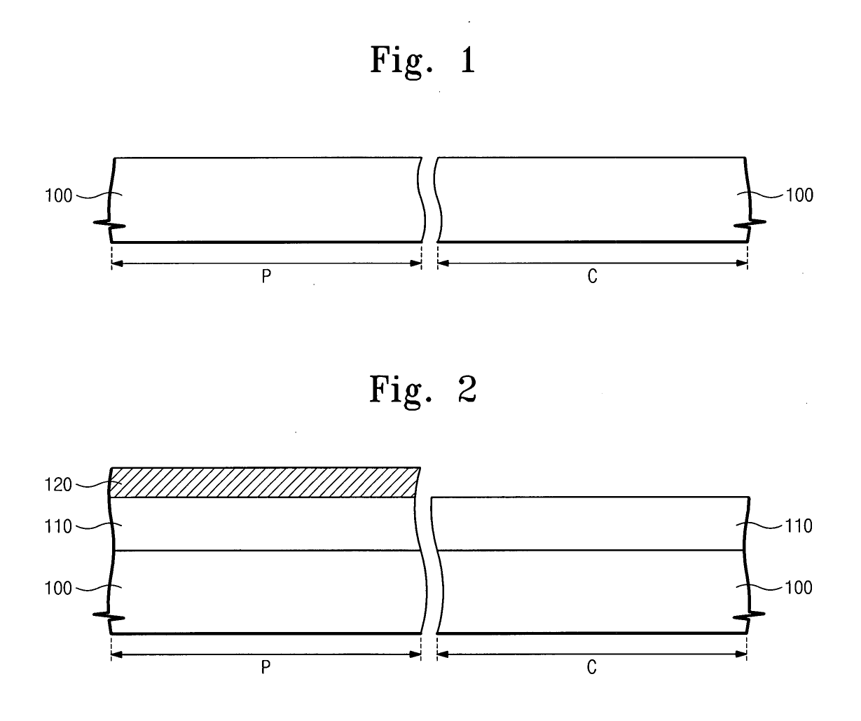

FIG. 1 illustrates a semiconductor substrate 100 that includes a semiconductor material such as silicon (Si). The semiconductor substrate 100 may have regions that are defined based on the functionality of components that are formed therein. For example, a DRAM can have a cell array region “C” and a peripheral circuit region “P”. The cell array region C includes memory components, such as capacitors. The peripheral circuit region P includes components, such as a resistor devices, that cooperatively function with the components in the cell array region C.

Referring now to FIG. 2, a first insulation layer 110 is formed on the semiconductor substrate 100. The first insulation layer 110 may be formed by chemical vapor deposition (CVD) or by another process. Components such as one or more gate lines and/or bit lines may be formed on the semiconductor substrate 100 before the first insulation layer 110 is formed thereon.

A ploysilicon layer 120 which serves as a resistor device layer is formed on the first insulation layer 110 in the peripheral circuit region P. For example, the ploysilicon layer 120 may be used to decrease external power supply voltages (e.g., 3.3 V) to levels that may be used to operate components in the semiconductor device (e.g., 1.7 V). Accordingly, for the ploysilicon layer 120 to serves as a resistor layer, it may be formed out of relatively high resistive materials (e.g., polysilicon which may include other materials) as compared to relatively low resistive materials such as metals.

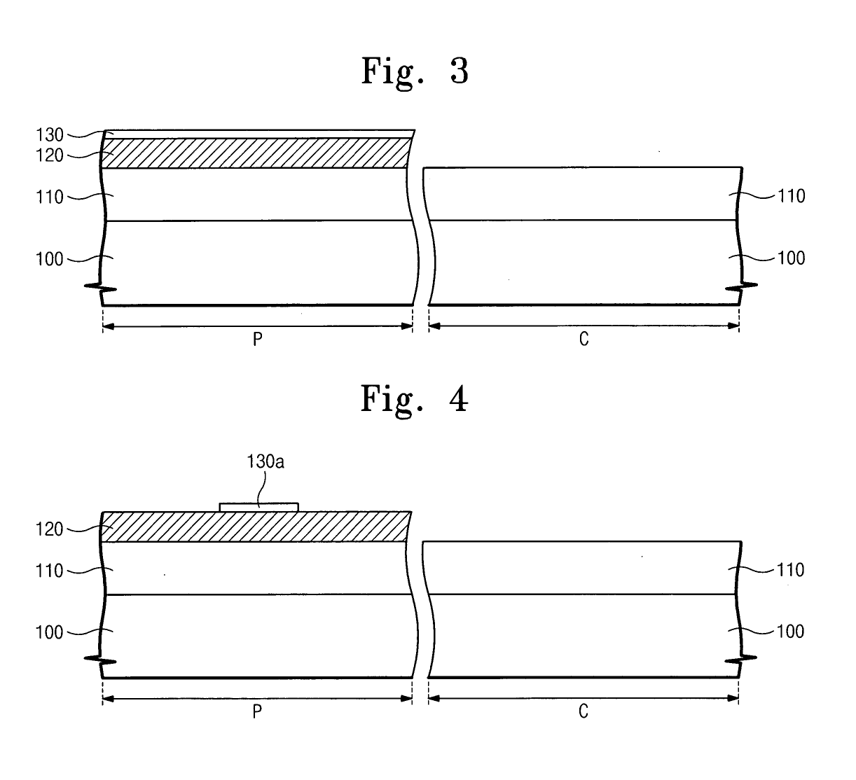

Referring to FIG. 3, a metal layer 130 is formed on top of the polysilicon layer 120. The metal layer 130 may be formed of a metal which can be used to form a local silicide region in the polysilicon layer 120 in a subsequent process. The metal layer 130 may be deposited by, for example, sputtering or chemical vapor deposition (CVD). The metal layer 130 may be formed from, for example, Tantalum (Ta), Nickel (Ni), Cobalt (Co), Tungsten (W), and/or Titanium (Ti).

Referring to FIG. 4, a metal pattern 130a is formed on a portion of the polysilicon layer 120 by removing a portion of the metal layer 130 by, for example, dry etching.

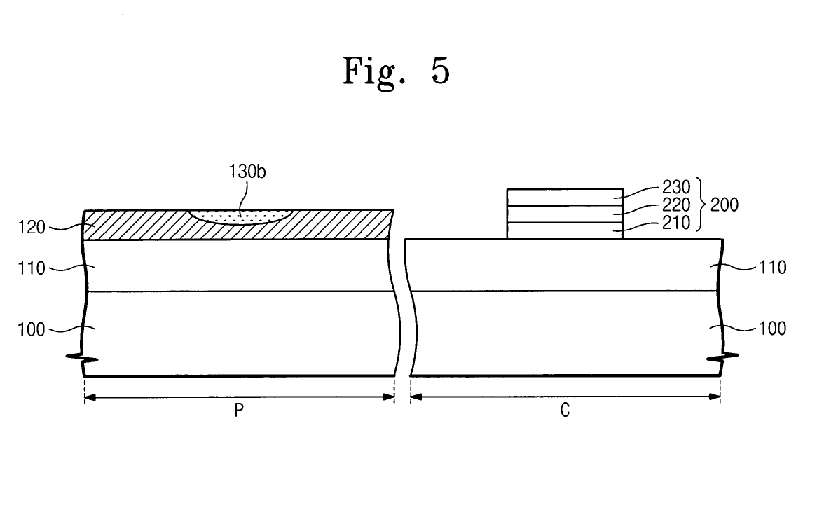

Referring to FIG. 5, the metal pattern 130a is annealed to form a local silicide region 130b in the polysilicon layer 120. The local silicide region 130b may include silicon (Si) and a material selected from the group of Titanium (Ti), Tantalum (Ta), Nickel (Ni), Cobalt (Co) and/or Tungsten (W).

If a metal contact were formed on a portion of the polysilicon layer 120 that does not include the silicide region 130b, an energy barrier may be formed by an energy band gap and work function at the connection that can cause carriers to move much more freely in one direction than in an opposite direction. Accordingly, the electrical resistance formed by a metal contact on the polysilicon layer 120 in the silicide region 130b can vary based upon the direction of the primary flow of carriers. In contrast, when a contact is formed on the silicide region 130b of the polysilicon layer 120, the silicide region 130b may serve as a transition area that may reduce or eliminate an energy barrier at the connection and may provide a more uniform resistance that may be independent of the direction of the primary flow of carriers.

The metal pattern 130(a) can react with the polysilicon layer 120 (e.g., TiSi₂) to form the silicide region 130b at temperatures of about 600° C. or higher. If the temperature is less than about 600° C., the silicide region 130b may be more incompletely formed, and may result in an increase in the contact resistance with a metal contact formed thereon. Accordingly, it may be desirable to anneal the metal pattern 130(a) on the polysilicon layer 120 to form the silicide region 130b at temperature of at least about 600° C.

The polysilicon layer 120 can have a constant thickness when the local silicide region 130b is formed on the polysilicon layer 120 by depositing the metal layer 130, patterning the metal layer 130 to form the metal pattern 130a, and annealing the metal pattern 130a to form the silicide region 130b. Forming the polysilicon layer 120 with a constant thickness can result in a more constant or uniform resistance.

In some other embodiments of the invention, the silicide region 130b is formed on the polysilicon layer 120 by depositing a metal layer, annealing the metal layer, and then etching the polysilicon layer 120. The metal layer 130 may be formed from, for example, Titanium (Ti), Tantalum (Ta), Nickel (Ni), Cobalt (Co) and/or Tungsten (W), which may be deposited through sputtering or CVD. When a metal layer is formed through CVD at a high temperature of at least about 600° C., the depositing of the metal layer and the formation of the silicide region may occur simultaneously. Accordingly, a subsequent annealing process may be omitted.

After the local silicide region 130b is formed, the capacitor 200 is formed on the first insulation layer 110 of the cell array region C. The capacitor 200 includes a bottom electrode 210, a dielectric layer 220 and an upper electrode 230. The bottom electrode 210, the dielectric layer 220 and the top electrode 230 are sequentially stacked on the first insulation layer 110. By forming the capacitor 200 after the local silicide region 130b is formed, the capacitor 200 is not subjected to the high temperature (e.g., above about 600° C.) used when annealing the metal pattern 130a, and which may thereby avoid the associated degradation affects on the capacitor 200, such as due to breakdown of the dielectric layer 220 and associated leakage of current, that can be caused by exposure to such high temperature. Consequently, the capacitor 200 may be a Metal Insulator Metal (MIS) structure and/or a Metal Insulator Metal (MIM) structure. For example, the capacitor 200 can have a MIM structure where the bottom and top electrodes 210 and 230 are metal (e.g., Titanium nitride (TiN)), and the dielectric layer 220 is a metal oxide (e.g., Tantalum oxide (TaO)).

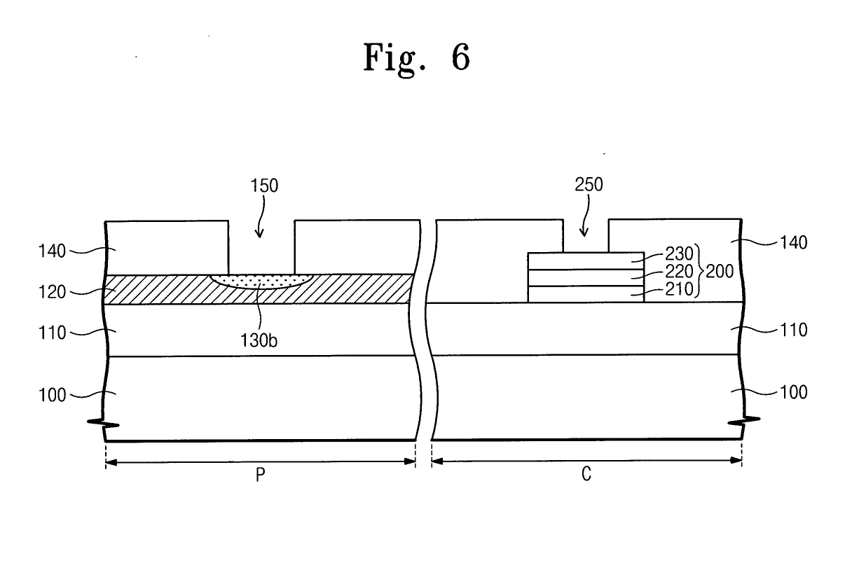

A plug can be formed on the first insulation layer 110 of the cell array region C to electrically connect the bottom electrode 210 of the capacitor 200 to the semiconductor substrate 100. For example, referring to FIG. 6, a second insulation layer 140 is formed on the polysilicon layer 120, and a contact hole 150 is formed that extends through the second insulation layer 140 to expose at least a portion of the local silicide region 130b. The local silicide region 130b may be substantially wider than the contact hole 150 in the second insulation layer 140. Forming the local silicide region 130b wider than the contact hole 150 may facilitate alignment of the contact hole 150 thereto and may improve the contact characteristics between the polysilicon layer 120 and a plug subsequently formed in the contact hole 150. The second insulation layer 140 may be formed by, for example, a CVD process. The contact hole 150 may be formed by, for example, anisotropic dry etching with good etching characteristic in a known direction. A via hole 250 is formed that penetrates the second insulation layer 140 to expose the top electrode 230 of the capacitor 200 in the cell array region C. The via hole 250 may be formed concurrently with the formation of the contact hole 150.

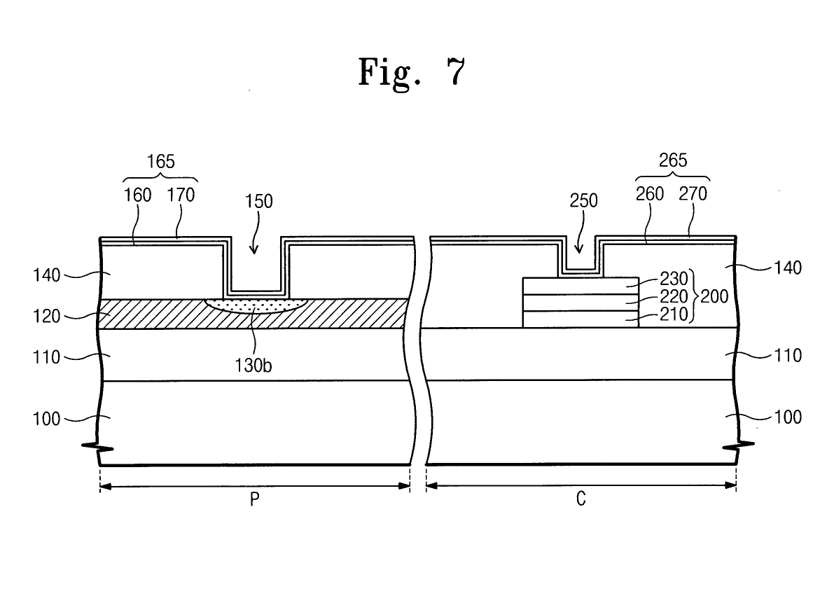

Referring to FIG. 7, a barrier layer 165 is formed in the contact hole 150 of the peripheral circuit region P. The barrier layer 165 may include a diffusion barrier layer 170 and a resistor layer 160. The resistor layer 160 may improve the resistive contact characteristics of, and adhesion to, the diffusion barrier layer 170. The resistor layer 160 is on, and may be directly on, the local silicide region 130b at the bottom of the contact hole 150. The resistor layer 160 may be a metal, such as Titanium (Ti), and/or may have an increased contact resistance by reacting Fluorine (F) with Titanium (Ti). Fluorine (F) may be used when the plug includes Tungsten (W) and the resistor layer 160 includes Titanium (Ti). Accordingly, the diffusion barrier layer 170 may be formed from Titanium nitride (TiN) after the resistor layer 160 is formed, and before a plug is formed.

As described above, the local silicide region 130b provides a contact portion of the polysilicon layer 120, and can be formed by a high temperature process at, for example, above about 600° C. prior to formation of the capacitor 200. Consequently, the capacitor 200 may be subjected to only low temperature processes at, for example, temperatures of less than about 550° C., and may thereby avoid breaking down of the dielectric layer 220 in the capacitor 200 and/or other degradation that may be caused if it were subjected to a high temperature process at temperatures of above about 600° C. Moreover, as described above, the local silicide region 130b of the polysilicon layer 120 may improving the resistive characteristics (e.g., constant/uniform and/or low contact resistance) at the contact between the resistor layer 160 and the polysilicon layer 120.

In some further embodiments of the present invention, a barrier layer 265 may be formed in the via hole 250 in the cell array region C. The barrier layer 265 may include a resistor layer 260 and a diffusion barrier layer 270. The resistor layer 260 and the diffusion barrier layer 270 in the cell array region C and the resistor layer 160 and the diffusion barrier layer 170 in the peripheral region P may be formed at the same time.

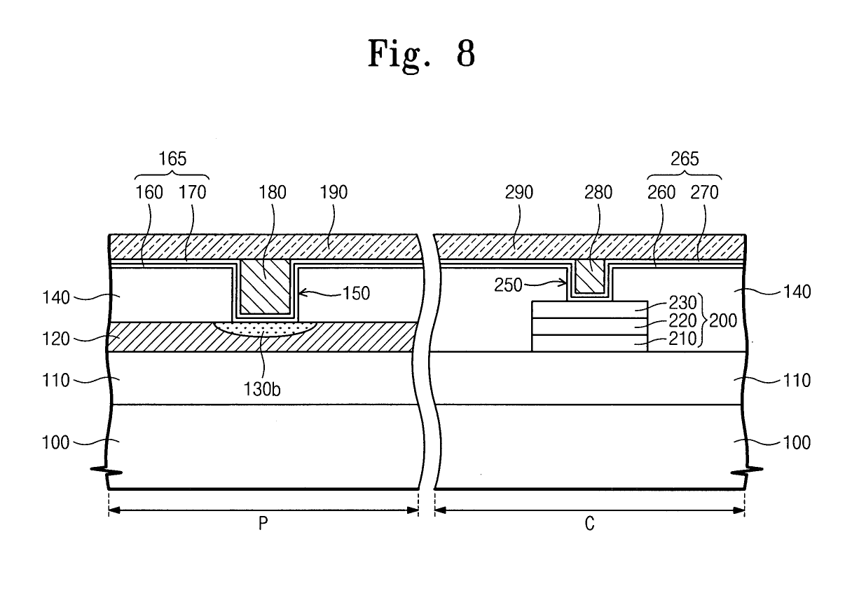

Referring to FIG. 8, a plug 180 is formed in the contact hole 150, and a metal interconnection 190 is formed on the second insulation layer 140 and in electrical contact with the plug 180. The plug 180 and the metal interconnection 190 may be formed of an electrically conductive material such as one or more metals (e.g., Aluminum (Al), Tungsten (W) and/or Copper (Cu)). The metal interconnection 190 may include Aluminum (Al) and/or Copper (Cu) which can provide good electrical conductivity. However, Aluminum (Al) may react with the polysilicon layer 120 to form a reaction product that increases the contact resistance. To avoid such reaction therebetween, the metal interconnection 190 may include Aluminum (Al) when the plug 180 includes Tungsten (W).

A plug 280 may be formed in the via hole 250 in the cell array region C, and may be formed at the same time as that the plug 180 is formed in the peripheral circuit region P. A metal interconnection 290 is formed on the barrier layer 265 and electrically connected to the plug 280, and may be formed at the same time as the metal interconnection 190.

In the drawings and specification, there have been disclosed preferred embodiments of the invention and, although specific terms are employed, they are used in a generic and descriptive sense only and not for purposes of limitation, the scope of the invention being set forth in the following claims.

What is claimed is:

1. A method of forming a contact in a semiconductor device, the method comprising the steps of:
providing a semiconductor substrate with a cell array region and a peripheral circuit region;
forming a polysilicon layer on the semiconductor substrate in the peripheral circuit region;
forming a metal layer on the polysilicon layer;
forming a metal pattern by removing a portion of the metal layer;
annealing the metal pattern to form a local silicide region in the polysilicon layer; and
forming a capacitor on the semiconductor substrate in the cell array region after forming the local silicide region in the polysilicon layer.

2. The method of claim 1, further comprising forming a first insulating layer on the semiconductor substrate in the cell array region and in peripheral circuit region, wherein the polysilicon layer is formed on the first insulating layer opposite to the semiconductor substrate.

3. The method of claim 2, wherein forming a capacitor comprises forming the capacitor on the first insulating layer in the cell array region after forming the local silicide region in the polysilicon layer.

4. The method of claim 2, further comprising:
forming a second insulation layer on the first insulation layer, the polysilicon layer, and the capacitor;
forming a contact hole through the second insulation layer to expose at least a portion of the local silicide region;
forming a plug in the contact hole; and
forming a metal interconnection electrically connected to the plug on the second insulation layer.

5. The method of claim 4, further comprising:
forming a resistor layer in the contact hole on the second insulating layer and on the local silicide region; and
forming a diffusion barrier layer in the contact hole on the resistor layer opposite the second insulating layer, wherein the plug is formed on the diffusion barrier layer.

6. The method of claim 4, wherein the local silicide region in the polysilicon layer is wider than the contact hole through the second insulation layer that exposes a portion of the local silicide region.

7. The method of claim 1, wherein the local silicide region in the polysilicon layer comprises silicon (Si) combined with Titanium (Ti), Tantalum (Ta), Nickel (Ni), Cobalt (Co) and/or Tungsten (W).

8. The method of claim 1, wherein the metal layer comprises Titanium (Ti), Tantalum (Ta), Nickel (Ni), Cobalt (Co) and/or Tungsten (W).

9. The method of claim 8, wherein forming the metal layer comprises sputtering and/or chemical vapor depositing the metal layer on the polysilicon layer.

10. The method the claim 1, wherein annealing the metal pattern comprises annealing the metal pattern at a temperature of about 600° C. or higher.

11. The method of claim 5, wherein:
forming a resistor layer comprises sputtering and/or chemical vapor depositing the resistor layer on the second insulating layer; and
forming a diffusion barrier layer comprises sputtering and/or chemical vapor depositing the diffusion barrier layer on the resistor layer.

12. The method of claim 5, wherein forming a resistor layer and forming a diffusion barrier layer is carried out at a temperature of not more than about 550° C.

13. The method of claim 12, wherein the resistor layer comprises Titanium (Ti).

14. The method of claim 5, wherein the diffusion barrier layer comprises Titanium nitride (TiN).

15. The method of claim 4, wherein the plug and/or the metal interconnection comprise Aluminum (Al), Tungsten (W) and/or Copper (Cu).

16. The method of claim 15, wherein:
the plug comprises Tungsten (W); and
the metal interconnection comprises Aluminum (Al).

17. The method of claim 1, wherein forming a capacitor comprises:
forming a bottom metal electrode;
forming a dielectric layer on the bottom metal electrode; and
forming a top metal electrode on the dielectric layer opposite to the bottom metal electrode.

18. The method of claim 17, wherein the dielectric layer comprises metal oxide.

19. A method of forming a contact in a semiconductor device, the method comprising the steps of:
providing a semiconductor substrate with a cell array region and a peripheral circuit region;
forming a first insulating layer on the semiconductor substrate in the cell array region and in peripheral circuit region;
forming a polysilicon layer on the first insulating layer in the peripheral circuit region;
forming a metal layer on the polysilicon layer;
forming a metal pattern by removing a portion of the metal layer;
annealing the metal pattern to form a local silicide region in the polysilicon layer;
forming a capacitor on the first insulating layer in the cell array region after forming the local silicide region in the polysilicon layer;
forming a second insulation layer on the first insulation layer, the polysilicon layer, and the capacitor;
forming a contact hole through the second insulation layer to expose at least a portion of the local silicide region;
forming a plug in the contact hole; and
forming a metal interconnection electrically connected to the plug on the second insulation layer.

20. A semiconductor device comprising:
a semiconductor substrate with a cell array region and a peripheral circuit region;
a polysilicon layer on the semiconductor substrate in the peripheral circuit region;
a local silicide region in the polysilicon layer;
a capacitor on the semiconductor substrate in the cell array region;
an insulation layer on the polysilicon layer and the capacitor;
a contact hole extending through the insulation layer and exposing a portion of the local silicide region, wherein the local silicide region is wider than the contact hole;
a plug in the contact hole; and
a metal interconnection electrically connected to the plug on the insulation layer.

21. The semiconductor device of claim 20, wherein the local silicide region in the polysilicon layer comprises silicon (Si) combined with Titanium (Ti), Tantalum (Ta), Nickel (Ni), Cobalt (Co), and/or Tungsten (W).
